(19) United States
(12) Patent Application Publication
(10) Pub. No.: US 2006/0072286 A1
(43) Pub. Date: Apr. 6, 2006

(54) [SWINGING DISPLAY MOUNTING STRUCTURE]

(75) Inventor: Hung-Chang Tseng, TAIPEI (TW)

Correspondence Address: BATON DIGITAL ELECTRONIC TECH. CO., LTD., P. O. BOX 108-00403, TAIPEI, TW

(73) Assignee: BATON DIGITAL ELECTRONIC TECH. CO., LTD., CHUNG-HO CITY (TW)

(21) Appl. No.: 10/711,797

(22) Filed: Oct. 6, 2004

(51) Int. Cl. H05K 7/00

(52) U.S. Cl. 361/681

(57) ABSTRACT

A swinging display mounting structure is disclosed to include a housing, which has a front receiving open chamber and can be installed in the headrest of a vehicle chair or the instrument of a motor vehicle, a display receivable to the front receiving open chamber of the housing, and a joint, which secures the display to the housing for enabling the display to be turned in the front receiving open chamber within 180 angles to have the display screen exposed to the outside or kept from sight.

### BACKGROUND OF THE INVENTION

1. Field of the Invention

The present invention relates to a swinging display mounting structure and more particularly, to such a swinging display mounting structure, which enables the display to be turned about an axis in a receiving open chamber in the front side of a housing and set between an exposed position and a hidden position.

2. Description of the Related Art

Since the invention of CRT (Cathode Ray Tube) in 1897, CRT has been intensively used in televisions and computer monitors for image output. However, following fast development of high technology, a variety of display devices including TFT LCD (Thin Film Transistor Liquid Crystal Display), PDP (Plasma Display Panel) and FPD (Flat Panel Display) have been developed for use to substitute for conventional CRT displays. Nowadays, motor computer systems use a TFT LCD instead of a conventional CRT monitor. PDP was commercialized in 1985. In Nagano Winter Olympics Japan, many Japanese manufacturers put different big size PDPs into the market. Following the step of TFT LCD, FED (Field Emission Display) has also been well developed to challenge the market.

For the advantages of fine picture quality, low radiation, zero magnetic wave, small size, and low power consumption, LCD has been intensively used in motor vehicles (cars, buses, and etc.). However, after installation of a LCD in a motor vehicle, for example, in the instrument panel or the headrest of a chair, the user cannot set the LCD in a received position to prevent damage of an external body to the display screen accidentally when the LCD is not in use. Further, because different users have different body sizes and a different sitting posture causes a change of the view angle, it may be necessary to adjust the angular position of a LCD in a motor vehicle to fit different users (passengers). However, conventional LCD mounting designs do not allow the user to adjust the angular position of the LCD. A LCD mounting design, which uses a bracket installed in the headrest of a vehicle's chair to support a LCD, enabling the user to adjust the angular position of the LCD. However, this design still has drawbacks. One drawback of this design is its limited adjustment range. Another drawback of this design is its big installation space requirement.

Further, because a LCD is a small but expensive device. When a car parked on a roadside or in a parking lot, the display in the car can easily be recognized from the outside of the car by a person passing by, thereby luring a thief to steal the LCD.

Therefore, it is desirable to provide a display mounting structure that eliminates the aforesaid problems.

### SUMMARY OF THE INVENTION

The present invention has been accomplished under the circumstances in view. It is therefore the main object of the present invention to provide a swinging display mounting structure, which allows the user to adjust the view angle of the display. It is another object of the present invention to provide a swinging display mounting structure, which allows the user to set the display between the operative position to have the display screen exposed to the outside, and the non-operative position to have the display screen kept from sight. To achieve these and other objects of the present invention, the swinging display mounting structure comprises a housing, which has a receiving open chamber, a display, and a joint coupled between the housing and the display to support the display in the receiving open chamber for enabling the display to be turned about an axis passing through the joint and set in one of a series of angular positions.

### BRIEF DESCRIPTION OF THE DRAWINGS

FIG. 1 is an exploded view of a swinging display mounting structure according to the first embodiment of the present invention.

FIG. 2 is an elevational assembly view of the swinging display mounting structure according to the first embodiment of the present invention.

FIG. 3 is a sectional view of the first embodiment of the present invention, showing the display set in the first position with the display screen exposed to the outside.

FIG. 4 is a sectional view of the first embodiment of the present invention, showing the display set in the second position with the display screen kept from sight.

FIG. 5 shows an application example of the first embodiment of the present invention.

FIG. 6 shows another application example of the first embodiment of the present invention.

FIG. 7 is a schematic sectional exploded view of a swinging display mounting structure according to the second embodiment of the present invention.

FIG. 8 is a perspective view of the second embodiment of the present invention.

### DETAILED DESCRIPTION OF EMBODIMENT

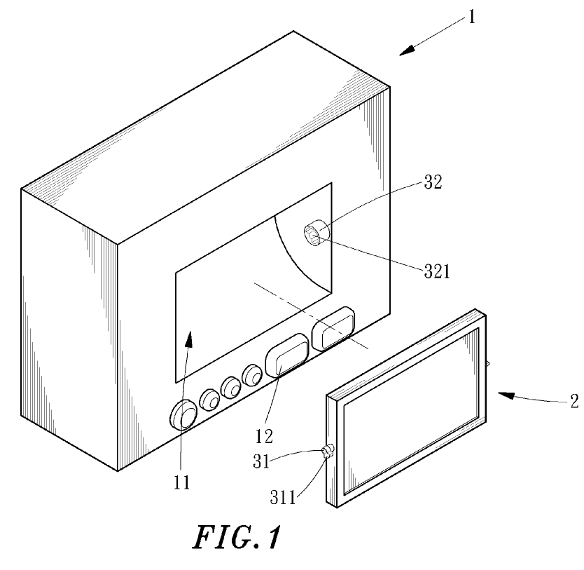

Referring to FIG. 1, a swinging display mounting structure in accordance with a first embodiment of the present invention is shown comprising a housing 1, a display 2, and a joint 3. The housing 1 has a front receiving open chamber 11, and a set of buttons 12 at the front side. The display 2 is a liquid crystal display receivable to the front receiving open chamber 11. The joint 3 is adapted to support the display 2 in the front receiving open chamber 11 and to hold the display 2 between two reversed positions. According to this embodiment, the joint 3 comprises two barrels 32 symmetrically provided at two opposite sides inside the front receiving open chamber 11, and two pivot pins 31 respectively provided at two opposite lateral sides of the display 2 and respectively pivoted to the barrels 32 for enabling the display 2 to be turned about the imaginary axis passing through the barrels 32 and the pivot pins 31. The barrels 32 each have a stop portion 321 projecting from the inside wall thereof. The pivot pins 31 each have a protruded locating portion 311 for stopping against one side of the stop portion 321 of the respective barrel 32. Further, electric wires (not shown) are extended out of the display through the pivot pins 31 (the pivot pins 31 are tubular pins) and the barrels 32 and electrically connected to the buttons 12 so that the user can operate the buttons 12 to control the operation of the display 2.

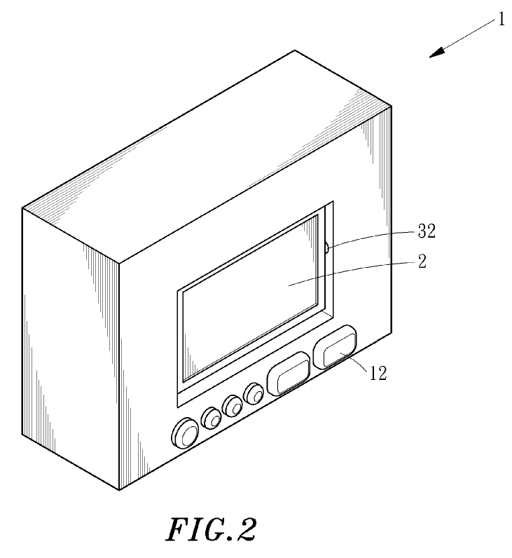

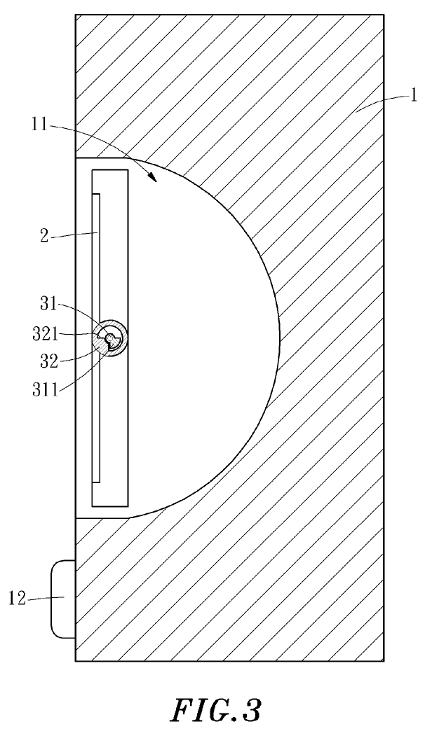

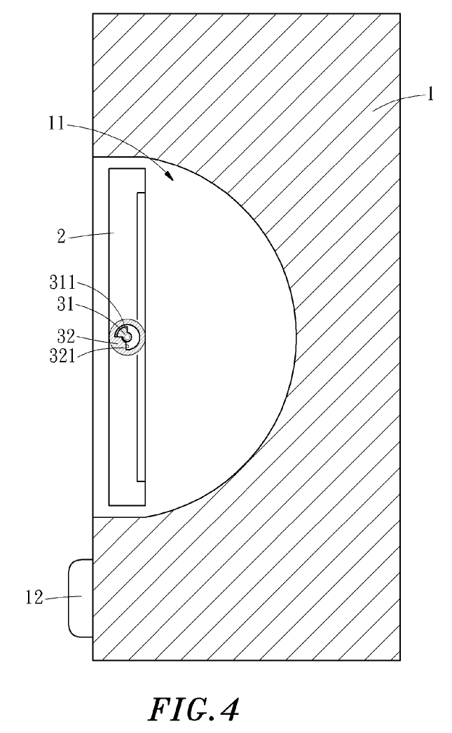

Referring to FIGS. 2˜4 and FIG. 1 again, the user can turn the display 2 about the imaginary axis passing through the barrels 32 and the pivot pins 31 between two positions, namely, the first position where the protruded locating portion 311 of each pivot pin 31 is respectively stopped at one side of the stop portion 321 of the respective barrel 32 and the display 2 has the display screen thereof exposed to the outside (see FIG. 3), and the second position where the protruded locating portion 311 of each pivot pin 31 is respectively stopped at the other side of the stop portion 321 of the respective barrel 32 and the display 2 has the display screen thereof received inside the housing 1 and kept from sight (see FIG. 4). Alternatively, the joint 3 can be so made that the display 2 can be selectively set in one of a series of angular positions.

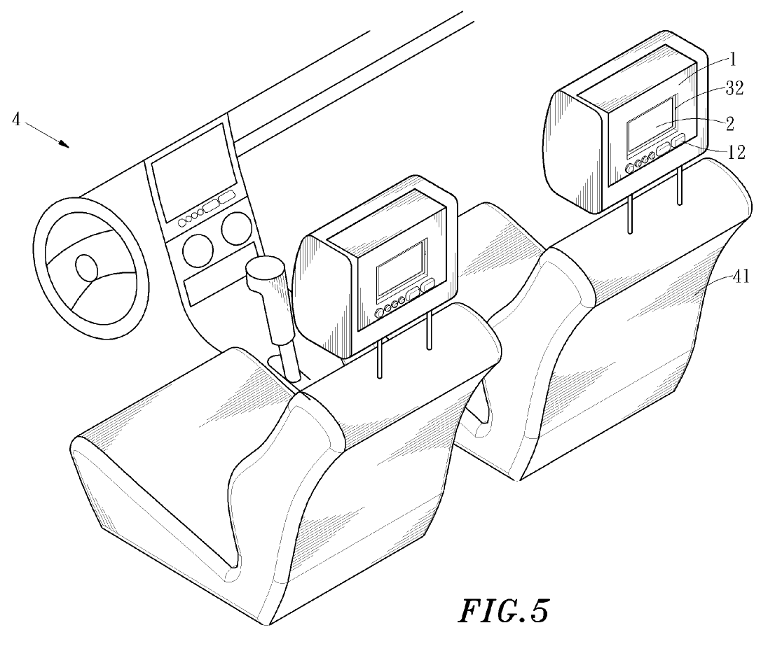

FIG. 5 shows an application example of the present invention. According to this application example, the housing 1 can be installed in the headrest of the driver or passenger's seat 41 inside a car.

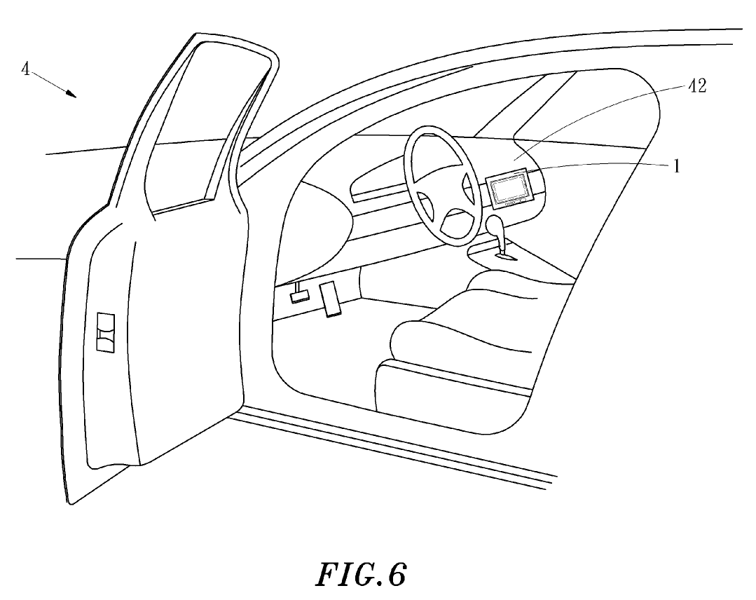

FIG. 6 shows another application example of the present invention. According to this application example, the housing 1 is installed in the instrument board 42 inside a car.

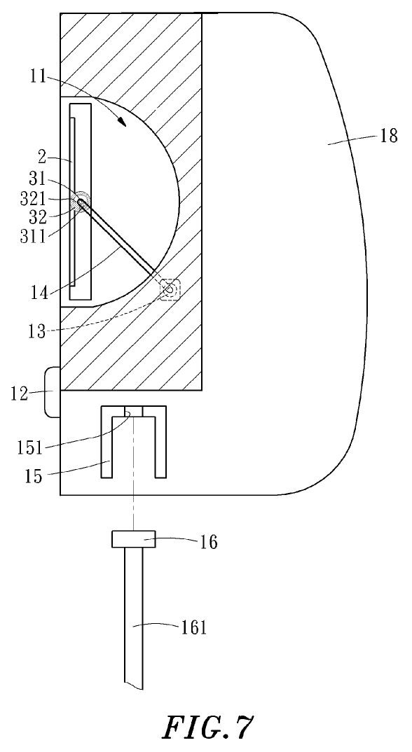

FIGS. 7 and 8 show a swinging display mounting structure according to a second embodiment of the present invention. According to this embodiment, the swinging display mounting structure comprises a housing 1, which has a front receiving open chamber 11 and a set of buttons 12 at the front side, a display 2 receivable to the front receiving open chamber 11, a soft covering 18 fastened to back and bottom sides of the housing 1 outside the front receiving open chamber 11, a joint 3, which comprises two barrels 32 symmetrically provided at two opposite sides inside the front receiving open chamber 11 and two pivot pins 31 respectively provided at two opposite lateral sides of the display 2 and respectively pivoted to the barrels 32 for enabling the display 2 to be turned about an imaginary axis passing through the barrels 32 and the pivot pins 31 between two reversed positions, drive means, for example, a reversible motor 13 mounted inside the housing 1, a transmission means, for example, a belt transmission mechanism 14 coupled between the motor 13 and the pivot pins 31 for turning the pivot pins 31 in the barrels 32 to move the display 2 between the two reversed directions, a channel bar 15, which is fixedly horizontally mounted in the bottom side of the housing 1 and which has a plurality of mounting holes 151 aligned in a line, two slotted sliding blocks 16, which are slidably inserted into the channel bar 15 and which each have a vertically downwardly extended mounting rod 161, and two screw bolts 17 respectively inserted through the slotted sliding blocks 16 and selectively fastened to the mounting holes 151 to affix the sliding blocks 16 to the channel bar 15. Similar to the aforesaid first embodiment, the barrels 32 each have a stop portion 321 projecting from the inside wall thereof. The pivot pins 31 each have a protruded locating portion 311 for stopping against one side of the stop portion 321 of the respective barrel 32.

A prototype of swinging display mounting structure has been constructed with the features of FIGS. 1˜8. The swinging display mounting structure functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A swinging display mounting structure comprising a housing, said housing having a receiving open chamber, a display, said display having a display screen, and a joint coupled between said housing and said display to support said display in said receiving open chamber for enabling said display to be turned about an axis passing through said joint and set in one of a series of angular positions.

2. The swinging display mounting structure as claimed in claim 1, wherein said joint comprises two barrels fixedly symmetrically provided at two opposite sides inside said receiving open chamber, and two pivot pins respectively provided at two opposite lateral sides of said display and respectively pivoted to said barrels.

3. The swinging display mounting structure as claimed in claim 2, wherein said barrels each have at least one stop portion projecting from an inside wall thereof; said pivot pins each have at least one protruded locating portion for stopping against the at least one stop portion of the respective barrel to hold said display in said receiving open chamber in one angular position.

4. The swinging display mounting structure as claimed in claim 1, wherein said housing comprises a plurality of buttons respectively electrically connected to said display for controlling the operation of said display.

5. The swinging display mounting structure as claimed in claim 1, wherein said housing is installed in the headrest of a chair inside a motor vehicle.

6. The swinging display mounting structure as claimed in claim 1, wherein said housing is installed in the instrument panel of a motor vehicle.

7. The swinging display mounting structure as claimed in claim 1, further comprises drive means adapted to rotate said pivot pins and said display relative to said barrels, and transmission means coupled between said drive means and said pivot pins.

8. The swinging display mounting structure as claimed in claim 7, wherein said drive means is a reversible motor.

9. The swinging display mounting structure as claimed in claim 7, wherein said transmission means is a belt transmission mechanism.

10. The swinging display mounting structure as claimed in claim 1, further comprising a channel bar fixedly horizontally mounted in a bottom side of said housing, said channel bar having a plurality of mounting holes aligned in a line, two slotted sliding blocks slidably inserted into said channel bar, said slotted sliding blocks each having a vertically downwardly extended mounting rod for mounting, and two screw bolts respectively inserted through said slotted sliding blocks and selectively fastened to the mounting holes of said channel bar to affix said sliding blocks to said channel bar.

11. The swinging display mounting structure as claimed in claim 10, further comprising soft cover means fixedly fastened to said housing outside said receiving open chamber for use as a headrest.
